(19) United States
(12) Patent Application Publication
(10) Pub. No.: US 2026/0101495 A1
(43) Pub. Date: Apr. 9, 2026

(54) INTEGRATED CIRCUIT DEVICES

(71) Applicant: Samsung Electronics Co., Ltd., Suwon-si (KR)

(72) Inventors: Kyunghwan Lee, Suwon-si (KR); Kilho Lee, Suwon-si (KR); Daewon Ha, Suwon-si (KR)

(21) Appl. No.: 19/093,350

(22) Filed: Mar. 28, 2025

(30) Foreign Application Priority Data
Oct. 7, 2024 (KR) 10-2024-0135961

(51) Int. Cl. H10B 12/00; H10D 30/01; H10D 30/68; H10D 30/69; H10D 64/01; H10D 64/68

(52) U.S. Cl. CPC H10B 12/20; H10D 30/689; H10D 30/6891; H10D 30/701; H10D 64/689; H10D 30/0411; H10D 30/0415; H10D 64/033

(57) ABSTRACT

An integrated circuit device includes a bit line extending on a substrate in a first direction, a channel layer extending on the bit line in a second direction perpendicular to the substrate, a floating metal layer spaced apart from the channel layer with a gate insulating layer therebetween on a first sidewall of the channel layer, a word line on a sidewall of the floating metal layer and extending in a third direction crossing the first direction, a ferroelectric layer between the word line and the sidewall of the floating metal layer, and a source line extending in the first direction The floating metal layer includes horizontal and vertical extension portions extending in the first and second directions, respectively. A contact area between the channel layer and the gate insulating layer is greater than a contact area between the ferroelectric layer and the floating metal layer.

### CROSS-REFERENCE TO RELATED APPLICATION

This application is based on and claims priority under 35 U.S.C. § 119 to Korean Patent Application No. 10-2024-0135961, filed on Oct. 7, 2024, in the Korean Intellectual Property Office, the disclosure of which is incorporated by reference herein in its entirety.

### TECHNICAL FIELD

The inventive concept relates to an integrated circuit device, and more particularly, to an integrated circuit device including a vertical channel transistor.

### BACKGROUND

To improve the performance and economic feasibility of products, the integration of semiconductor devices may be increased. Particularly, the integration of semiconductor devices may be an important factor in determining the economic feasibility of products. Since the integration of two-dimensional memory devices may largely be determined by the area occupied by unit memory cells, the integration of two-dimensional memory devices may be greatly influenced by the level of technologies for forming fine patterns. However, the area of the chip die is limited and expensive equipment may be required to form fine patterns. Thus, there may still be limitations on the integration of two-dimensional memory devices as the integration of two-dimensional memory devices increases.

### SUMMARY

The inventive concept provides an integrated circuit device with improved electrical characteristics.

In addition, the inventive concept is not limited to the mentioned above, and other inventive concepts may be clearly understood by those skilled in the art.

To achieve the inventive concept, integrated circuit devices as follows are provided.

According to an aspect of the inventive concept, there is provided an integrated circuit device, including a substrate, a bit line extending on the substrate in a first direction parallel to an upper surface of the substrate, a channel layer extending on the bit line in a second direction perpendicular to the upper surface of the substrate,, and including a first sidewall, a floating metal layer spaced apart from the channel layer in the first direction, a gate insulating layer between the floating metal layer and the channel layer, wherein the gate insulating layer is on the first sidewall of the channel layer, a word line on at least one sidewall of the floating metal layer and extending in a third horizontal direction parallel to an upper surface of the substrate and crossing the first direction, a ferroelectric layer between the word line and the at least one sidewall of the floating metal layer, and a source line electrically connected to the channel layer and extending in the first direction, wherein the floating metal layer includes a horizontal extension portion extending in the first direction and a vertical extension portion extending in the second direction, and an area of contact between the channel layer and the gate insulating layer is greater than an area of contact between the ferroelectric layer and the floating metal layer.

According to another aspect of the inventive concept, there is provided an integrated circuit device, including a substrate, a bit line extending on the substrate in a first direction parallel to an upper surface of the substrate, a source region on the bit line and including p-type impurities, a channel layer on the source region, extending in a second direction perpendicular to the upper surface of the substrate, and including a first sidewall, a gate insulating layer on the first sidewall of the channel layer and on an upper surface of the source region, a floating metal layer including a first floating metal layer and a second floating metal layer, the first floating metal layer is on the upper surface of the source region, and the second floating metal layer is on the first sidewall of the channel layer, and the gate insulating layer is between the channel layer and the floating metal layer and between the source region and the floating metal layer, a word line on an upper surface of the first floating metal layer, wherein a ferroelectric layer is between the first floating metal layer and the word line and between the second floating metal layer and the word line, a drain region on an upper surface of the channel layer and including p-type impurities, and a source line electrically connected to the drain region and extending in the first direction, wherein a thickness of the first floating metal layer in the second direction is greater than a thickness of the second floating metal layer in the first direction, and an area of contact between the channel layer and the gate insulating layer is greater than an area of contact between the ferroelectric layer and the floating metal layer.

According to another aspect of the inventive concept, there is provided an integrated circuit device, including a substrate, a bit line extending on the substrate in a first direction parallel to an upper surface of the substrate, a mold insulating layer on the substrate and on the bit line and including a hole therein, a source region in the hole of the mold insulating layer, on an upper surface of the bit line, and including p-type impurities, a channel layer in the hole of the mold insulating layer and extending on the source region in a second direction perpendicular to an upper surface of the substrate, the channel layer including polysilicon, silicon germanium, an oxide semiconductor material, or a two-dimensional material, and including a first sidewall and a second sidewall opposite each other, wherein the second sidewall is in contact with the mold insulating layer, a gate insulating layer and a floating metal layer in the hole of the mold insulating layer the gate insulating layer extending in the second direction on the first sidewall of the channel layer and in the first direction on an upper surface of the source region, a ferroelectric layer in the hole of the mold insulating layer and conformally extending on a sidewall of a vertical extension portion of the floating metal layer and an upper surface of a horizontal extension portion of the floating metal layer, the ferroelectric layer having a conformal thickness, a word line in the hole of the mold insulating layer and on the ferroelectric layer, a drain region in the hole of the mold insulating layer, on an upper surface of the channel layer, and including p-type impurities, and a source line electrically connected to the drain region and extending in the first direction, wherein a thickness of the horizontal extension portion of the floating metal layer in the second direction is greater than a thickness of the vertical extension portion of the floating metal layer in the first direction, an area of contact between the channel layer and the gate insulating layer is greater than an area of contact between the ferroelectric layer and the floating metal layer, and a thickness of the ferroelectric layer is not greater than 20 nm.

### BRIEF DESCRIPTION OF THE DRAWINGS

Embodiments will be more clearly understood from the following detailed description taken in conjunction with the accompanying drawings in which:

FIG. 1 is a circuit diagram of an integrated circuit device according to embodiments;

FIG. 2 is a layout diagram of an integrated circuit device according to embodiments;

FIG. 3A and FIG. 3B are a cross-sectional view and a top view of a portion of a cell array area in FIG. 2, respectively, according to embodiments;

FIG. 4 is a cross-sectional view of a portion of a cell array area in FIG. 2, according to embodiments;

FIG. 5 is a cross-sectional view of a portion of a cell array area in FIG. 2, according to embodiments;

FIG. 6 is a cross-sectional view of a portion of a cell array area in FIG. 2, according to embodiments;

FIG. 7A and FIG. 7B are a cross-sectional view and a top view of a portion of a cell array area in FIG. 2, respectively, according to embodiments;

FIG. 8A and FIG. 8B are a cross-sectional view and a top view of a portion of a cell array area in FIG. 2, respectively, according to embodiments;

FIG. 9A and FIG. 9B are a cross-sectional view and a top view of a portion of a cell array area in FIG. 2, respectively, according to embodiments; and

FIGS. 10A, 10B, 11A, 11B, 12A, 12B, 13A, 13B, 14A, 14B, 15, 16A, 16B, 17A, 17B, 18, 19A, 19B, 20A, 20B, 21A, 21B, 22A, 22B, 23A, 23B, 24A, and 24B are schematic diagrams illustrating a method of manufacturing an integrated circuit device, according to embodiments, wherein FIGS. 10A, 11A, 12A, 13A, 14A, 16A, 17A, 18, 19A, 20A, 21A, 22A, 23A, and 24A are cross-sectional views of each structure formed during the manufacturing process, and FIGS. 10B, 11B, 12B, 13B, 14B, 15, 16B, 17B, 19B, 20B, 21B, 22B, 23B, and 24B are top views of each structure formed during the manufacturing process.

### DETAILED DESCRIPTION OF EMBODIMENTS

Hereinafter, embodiments are described in detail with reference to the accompanying drawings. The same reference numerals are used for the same components in the drawings and redundant description thereof is omitted.

Since the embodiments are subject to various transformations and have various embodiments, specific embodiments may be illustrated in the drawings and described in detail in the detailed description. However, this is not intended to limit the scope to specific embodiments, and shall be understood to include all transformations, equivalents, and substitutes included in the inventive concept. In describing the embodiments, detailed description of the related art may be omitted.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection and may refer to a direct or indirect physical and/or electrical connection. When an element is referred to as being “directly on” or “directly contacting” another element, there are no intervening elements present. The term “exposed,” may be used to describe relationships between elements and/or certain intermediate processes in fabricating a completed semiconductor device, but may not necessarily require exposure of the particular region, layer, structure or other element in the context of the completed device.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In the drawings, the thickness of elements, layers, films, regions, etc., may be exaggerated for clarity. For example, illustrations of relative contact areas between layers shown in particular cross-sections or regions may not necessarily be representative of the actual contact areas between the layers in the context of the overall device.

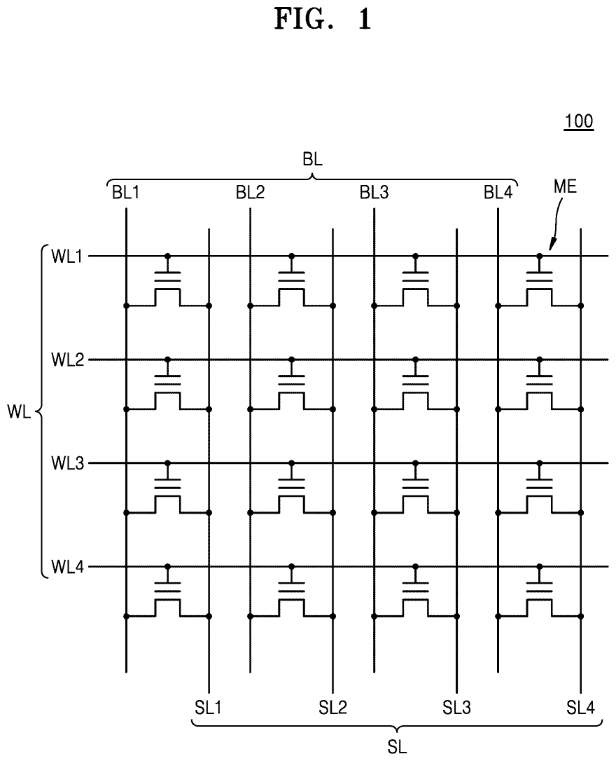

FIG. 1 is a circuit diagram of an integrated circuit device 100, according to embodiments.

Referring to FIG. 1, the integrated circuit device 100 may include a plurality of memory units ME arranged between a plurality of word lines WL and a plurality of bit lines BL. The plurality of memory units ME may include a charge trap type transistor. For example, each memory unit ME may be arranged at an intersection of each of first to fourth word lines WL1, WL2, WL3, and WL4 and each of first to fourth bit lines BL1, BL2, BL3, and BL4. A gate of the memory unit ME may be connected to the word line WL, a drain terminal of the memory unit ME may be connected to the bit line BL, and a source terminal of the memory unit ME may be connected to the source line SL. In embodiments, first to fourth source lines SL1, SL2, SL3, and SL4 may extend horizontally with the first to fourth bit lines BL1, BL2, BL3, and BL4, but are not limited thereto. The plurality of memory units ME may include a charge trap type transistor and the integrated circuit device 100 may include a capacitor-less dynamic random-access memory (DRAM) device including a cross-point type transistor.

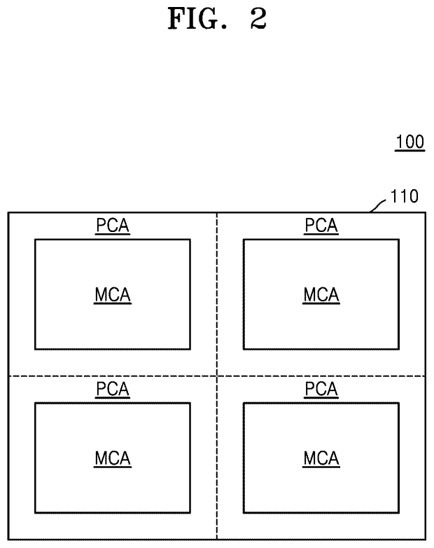

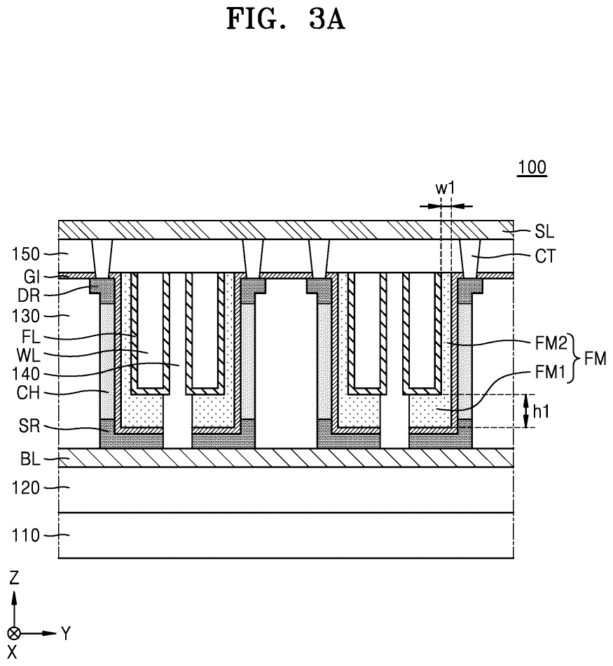

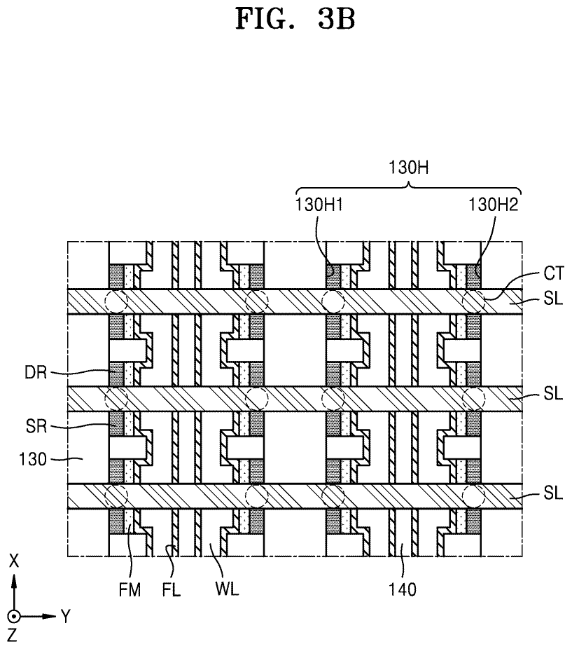

FIG. 2 is a layout diagram of an integrated circuit device 100, according to embodiments. FIG. 3A and FIG. 3B are a cross-sectional view and a top view of a portion of a cell array area MCA in FIG. 2, respectively, according to embodiments.

Referring to FIGS. 2, 3A, and 3B, the integrated circuit device 100 may include a substrate 110 including a cell array area MCA and a peripheral circuit area PCA. In embodiments, the cell array area MCA may include a memory cell area of an integrated circuit device and the peripheral circuit area PCA may include a core area or a peripheral circuit area of the integrated circuit device. For example, the peripheral circuit area PCA may include a peripheral circuit transistor (not shown) for transmitting signals and/or power to a memory cell array included in the cell array area MCA. In embodiments, the peripheral circuit transistor (not shown) may include various circuits, such as a command decoder, control logic, an address buffer, a row decoder, a column decoder, a sense amplifier, and a data input/output circuit.

As shown in FIGS. 3A and 3B, a plurality of word lines WL extending in a first horizontal direction (X direction), a plurality of bit lines BL extending in a second horizontal direction (Y direction), and a plurality of source lines SL extending in the second horizontal direction (Y direction) may be disposed above the cell array area MCA of the substrate 110. The plurality of memory units ME may be arranged at intersections of the plurality of word lines WL and the plurality of bit lines BL. The plurality of memory units ME may include a trap-type transistor or a trap-type memory device.

In embodiments, the plurality of memory units ME may include a first memory unit ME and a second memory unit ME that are arranged symmetrically to each other. The first word line WL1 and the second word line WL2 between the first memory unit ME and the second memory unit ME may be spaced apart from each other.

As shown in FIG. 3A, a lower insulating layer 120 may be disposed on the substrate 110. The substrate 110 may include silicon, for example, single-crystalline silicon, polycrystalline silicon, or amorphous silicon. In other embodiments, the substrate 110 may include at least one selected from germanium (Ge), silicon germanium (SiGe), silicon carbide (SiC), gallium arsenide (GaAs), indium arsenide (InAs), and/or indium phosphide (InP). In embodiments, the substrate 110 may include a conductive region, e.g., a well doped with impurities or a structure doped with impurities. The lower insulating layer 120 may include an oxide film, a nitride film, or a combination thereof.

A bit line BL extending in the second horizontal direction (Y direction) may be disposed on the lower insulating layer 120. In embodiments, the bit line BL may include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), polysilicon, or a combination thereof. A first insulating layer 122 may be disposed on the lower insulating layer 120 to cover a sidewall of the bit line BL and have an upper surface coplanar with the bit line BL.

A mold insulating layer 130 may be disposed on the bit line BL and the first insulating layer 122. The mold insulating layer 130 may include a plurality of holes 130H. The mold insulating layer 130 may include an oxide film, a nitride film, a low-k dielectric film, or a combination thereof.

Two memory units ME may be arranged in each of the plurality of holes 130H of the mold insulating layer 130. The two memory units ME arranged in one hole 130H may be symmetrical to each other. In embodiments, one hole 130H includes a first sidewall and a second sidewall facing each other. The first memory unit ME disposed on the first sidewall of the hole 130H may be symmetrical to the second memory unit ME disposed on the second sidewall of the hole 130H with respect to a central portion of the hole 130H.

Each of the plurality of memory units ME may include a source region SR, a channel layer CH, a floating metal layer FM, a ferroelectric layer FL, and a gate insulating layer GI, each arranged within the plurality of holes 130H.

The source region SR may be arranged at the bottom of the hole 130H of the mold insulating layer 130 and on the upper surface of the bit line BL. The source region SR may include at least one of p-type impurity-doped polysilicon, p-type impurity-doped SiGe, and/or p-type impurity-doped two-dimensional material, e.g., hexagonal boron nitride, transition metal dichalcogenide, or graphene.

The channel layer CH may be disposed on the upper surface of the source region SR and may extend in a vertical direction (Z direction). The mold insulating layer 130 may be disposed on one sidewall of the channel layer CH and the gate insulating layer GI may be disposed on the other sidewall of the channel layer CH. The channel layer CH may include at least one of polysilicon, SiGe, and a two-dimensional material, e.g., hexagonal boron nitride, transition metal dichalcogenide, or graphene.

A drain region DR may be disposed on the upper surface of the channel layer CH. One sidewall of the drain region DR may contact the mold insulating layer 130 and the other sidewall of the drain region DR may contact the gate insulating layer GI. A contact CT may be disposed on the drain region DR. The drain region DR may include at least one of p-type impurity-doped polysilicon, p-type impurity-doped SiGe, and p-type impurity-doped two-dimensional material, e.g., hexagonal boron nitride, a transition metal dichalcogenide, or graphene.

The floating metal layer FM may include a first floating metal layer FM1 and a second floating metal layer FM2. In embodiments, the first floating metal layer FM1 may extend in the second horizontal direction (Y direction) with a conformal thickness from the gate insulating layer GI extending on the source region SR. As used herein, a “conformal thickness” may refer to the thickness of a layer that conformally extends on underlying surfaces or elements, where the thickness may be substantially uniform. The first floating metal layer FM1 may have a first height h1 in the vertical direction (Z direction). In embodiments, the second floating metal layer FM2 may extend in the vertical direction (Z direction) between the ferroelectric layer FL and the gate insulating layer GI. The upper surface of the second floating metal layer FM2 may be at the same vertical level as the uppermost surface of the gate insulating layer GI. The second floating metal layer FM2 may have a first width w1 in the second horizontal direction (Y direction). As used herein, a “level” of an element or component may refer to a distance of the element or component (or a sublayer of a layer structure including the element or component therein) from a reference layer or surface. The first floating metal layer FM1 and the second floating metal layer FM2 may include the same material in some embodiments.

The ferroelectric layer FL may include a ferroelectric material. In particular, when the ferroelectric layer FL includes a hafnium (Hf)-based material, the ferroelectric layer FL may include a dopant of at least one selected from zirconium (Zr), silicon (Si), aluminum (Al), yttrium (Y), gadolinium (Gd), lanthanum (La), scandium (Sc), strontium (Sr), and/or combinations thereof. Although the ferroelectric layer FL is shown as a single layer in FIGS. 3A and 3B, this is merely an example. The ferroelectric layer FL may have a multilayer structure.

In embodiments, the ferroelectric layer FL may be formed by alternately stacking different types of ferroelectric material layers one or more times. In embodiments, the ferroelectric layer FL may be formed by alternately stacking a ferroelectric material layer and a dielectric material layer one or more times. In embodiments, the ferroelectric layer FL may be formed by alternately stacking a ferroelectric material layer and an antiferroelectric material layer one or more times. In embodiments, the ferroelectric layer FL may be formed by alternately stacking an antiferroelectric material layer and a dielectric material layer one or more times. In embodiments, the ferroelectric layer FL may include a material having a different work function from the material included in the floating metal layer FM and the word line WL.

In the integrated circuit device 100 of the inventive concept, the area of contact between the channel layer CH and the gate insulating layer GI is greater than the area of contact between the ferroelectric layer FL and the floating metal layer FM. Thus, the effect of increasing or improving the memory window (which may refer to a voltage difference between the threshold voltages corresponding to the respective polarization states of the ferroelectric layer) may be achieved. In addition, since the ferroelectric layer FL and the gate insulating layer GI are not directly in contact with each other and are separated from each other by the floating metal layer FM therebetween, the interfacial characteristics of the ferroelectric layer FL may not be deteriorated, thereby achieving excellent scattering and improving electrical reliability of the device.

The area ratio of the gate insulating layer GI to the ferroelectric layer FL may be adjusted to adjust the offset of the integrated circuit device 100. That is, to increase the area ratio of the ferroelectric layer FL to the gate insulating layer GI area, the first height h1, which is the height of the lower surface or thickness of the horizontal portion FM1 of the floating metal layer FM, may be greater than the first thickness w1 of the sidewall or vertical portion FM2 of the floating metal layer FM. Alternatively, although not shown herein, only a portion of the floating metal layer FM extending in the second horizontal direction (Y direction) may be formed without having the “L” shape, that is, only the first floating metal layer FM1 may be formed without the second floating metal layer FM2.

In embodiments, the gate insulating layer GI may include at least one selected from a high-k dielectric material and a ferroelectric material having a higher dielectric constant than silicon oxide. In embodiments, the gate insulating layer GI may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanate oxide (SrTiO), yttrium oxide (YO), aluminum oxide (AlO), or lead scandium tantalum oxide (PbScTaO).

In embodiments, the word line WL may include Ti, TiN, Ta, TaN, molybdenum (Mo), ruthenium (Ru), W, WN, TiSiN, WSiN, polysilicon, or a combination thereof.

A buried insulating layer 140 may be arranged between two word lines WL arranged in the hole 130H of the mold insulating layer 130. In embodiments, the buried insulating layer 140 may be in a structure in which a plurality of insulating layers are stacked. In embodiments, the buried insulating layer 140 may include an insulating liner that is in contact with the word line WL and includes a first insulating material, and an insulating layer that is not in direct contact with the word line WL, fills a space between the two word lines WL, and includes a second insulating material that is different from the first insulating material. The term “fill” or “cover” or “surround” as may be used herein may not require completely filling or covering or surrounding the described elements or layers, but may, for example, refer to partially filling or covering or surrounding the described elements or layers, for example, with voids, spaces, or other discontinuities throughout.

An upper insulating layer 150 may be arranged to cover the memory unit ME, the word line WL, and the buried insulating layer 140, each on the mold insulating layer 130. The source line SL extending in the second horizontal direction (Y direction) may be disposed on the upper insulating layer 150, and the contact CT may be arranged between the source line SL and the drain region DR through the upper insulating layer 150. For example, the contact CT may include Ti, TiN, Ta, TaN, W, WN, TiSiN, WSiN, polysilicon, or a combination thereof.

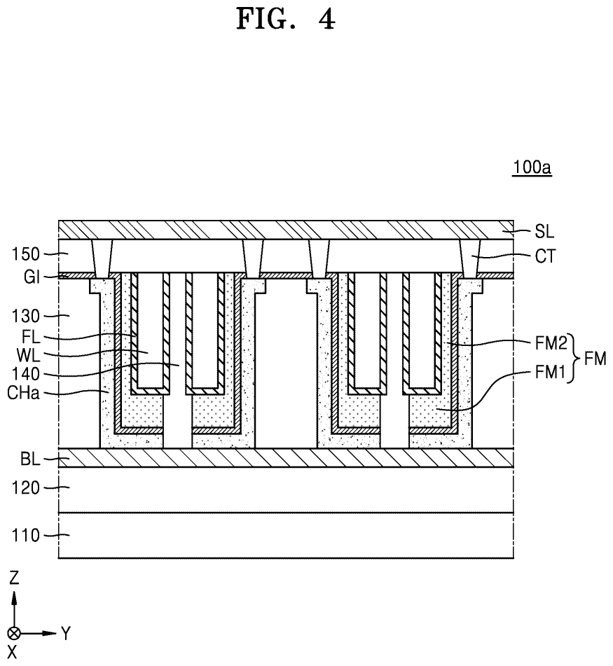

FIG. 4 is a cross-sectional view of a portion of a cell array area in FIG. 2, according to embodiments.

It may be understood that an integrated circuit device 100a of FIG. 4 is not mutually exclusive with the integrated circuit device 100 described with reference to FIGS. 3A and 3B and elements having the same reference numerals are the same. Hereinafter, descriptions that are substantially the same as those given above may be omitted. The differences between the integrated circuit device 100a of FIG. 4 and the integrated circuit device 100 of FIGS. 3A and 3B may be mainly described.

Referring to FIG. 4, unlike the integrated circuit device 100 of FIGS. 3A and 3B in which the source region SR and the drain region DR are respectively arranged at both or opposing ends of the channel layer CH, a channel layer CHa may include an oxide semiconductor material.

When the channel layer CHa includes an oxide semiconductor material, the channel layer CHa may include at least one selected from, for example, IGZO, Sn-IGZO, indium tungsten oxide (IWO), copper disulfide (CuS₂), copper diselenide (CuSe₂), tungsten diselenide (WSe₂), indium zinc oxide (IZO), ZnSnO (ZTO), yttrium zinc oxide (YZO), and/or combinations thereof.

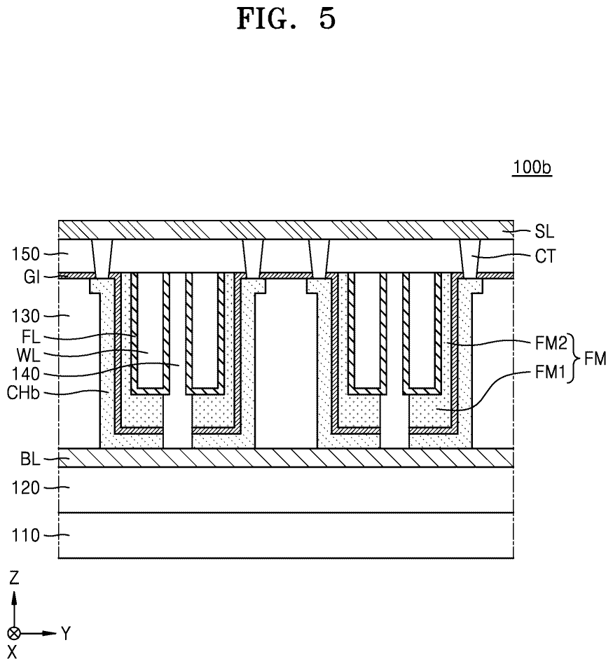

FIG. 5 is a cross-sectional view of a portion of a cell array area in FIG. 2, according to embodiments.

It may be understood that an integrated circuit device 100b of FIG. 5 is not mutually exclusive with the integrated circuit device 100 described with reference to FIGS. 3A and 3B and elements having the same reference numerals are the same. Hereinafter, descriptions that are substantially the same as those given above may be omitted. The differences between the integrated circuit device 100b of FIG. 5 and the integrated circuit device 100 of FIGS. 3A and 3B may be mainly described.

Referring to FIG. 5, unlike the integrated circuit device 100 of FIGS. 3A and 3B in which the source region SR and the drain region DR are respectively arranged at both or opposing ends of the channel layer CH, a channel layer CHb may include a two-dimensional (2D) material. When the channel layer CHb includes a 2D material, the channel layer CHb may include at least one selected from, for example, molybdenum disulfide (MoS₂), molybdenum diselenide (MoSe₂), tungsten disulfide (WS₂), and/or combinations thereof. However, this is merely an example material. The channel layer CHb may also include other 2D materials.

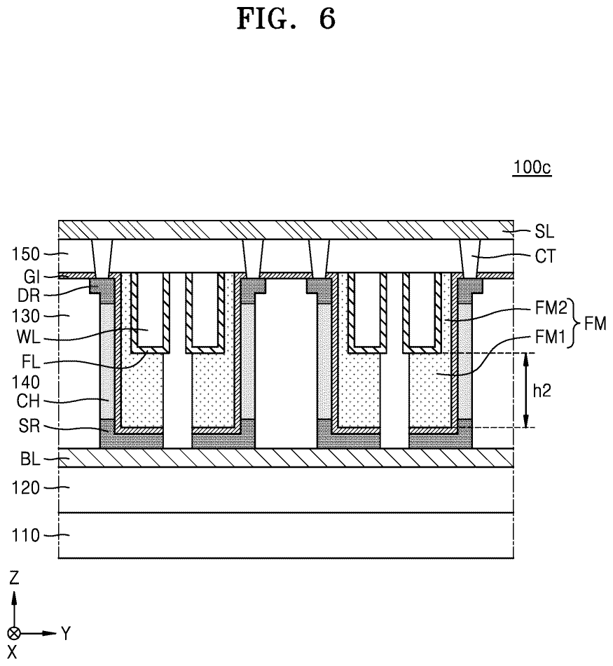

FIG. 6 is a cross-sectional view of a portion of a cell array area in FIG. 2, according to embodiments.

A second height h2, which is the height of the lower surface of a floating metal layer FM included in an integrated circuit device 100c of FIG. 6, may be greater than the first height h1, which is the height of the lower surface of the floating metal layer FM included in the integrated circuit device 100 of FIG. 3A. That is, the thickness of a first floating metal layer FM1 of the integrated circuit device 100c of FIG. 6 may be greater than that of the first floating metal layer FM1 of the integrated circuit device 100 of FIG. 3A.

As described above, the thickness of the floating metal layer FM may be adjusted to adjust the offset of the integrated circuit device. As the thickness of the first floating metal layer FM1 in the vertical direction (Z direction) increases, the area of contact or interface between the channel layer CH and the gate insulating layer GI (also referred to as a first contact area) may be greater than the area of contact or interface between the ferroelectric layer FL and the floating metal layer FM (also referred to as a second contact area). That is, the height or thickness of the first floating metal layer FM1 may be adjusted to reduce the relative contact area between the floating metal layer FM and the ferroelectric layer FL, so as to easily adjust the offset of the integrated circuit device and to easily adjust the memory window.

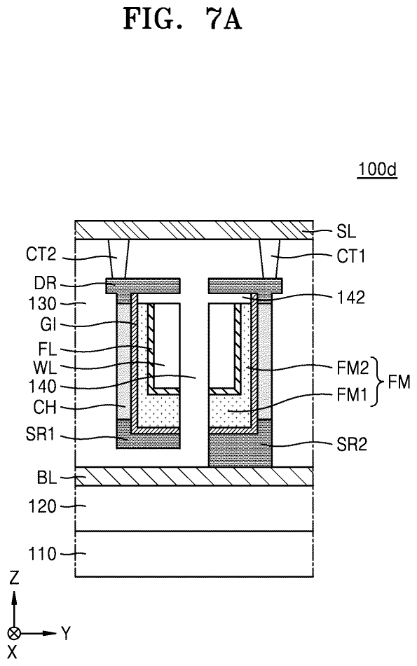

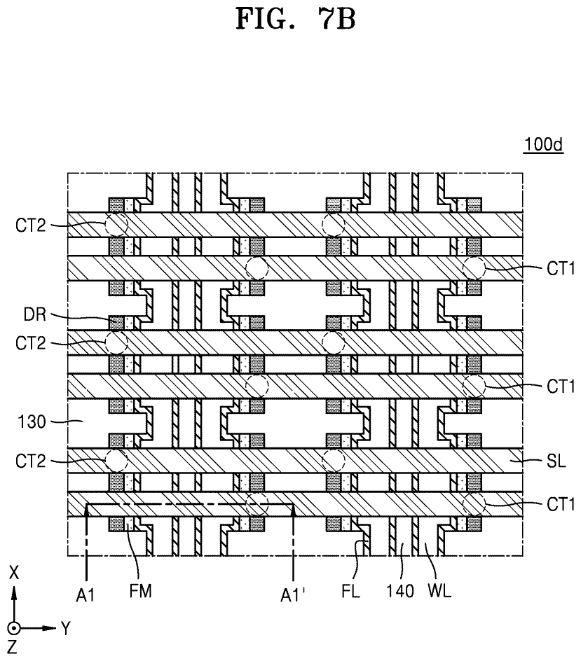

FIG. 7A and FIG. 7B are a cross-sectional view and a top view of a portion of a cell array area in FIG. 2, respectively, according to embodiments. Specifically, FIG. 7A may be a cross-sectional view taken along line A1-A1′ in FIG. 7B.

Referring to FIGS. 7A and 7B, contacts CT1 and CT2 of an integrated circuit device 100d may be formed in a zigzag form from a plan view. That is, the first contact CT1 and the second contact CT2 may be formed on different source lines SL. Thus, while the first contact CT1 is in direct contact with the drain region DR, the second contact CT2 formed on the other source line SL may be spaced apart from the drain region DR in the cross-section taken along line A1-A1′ even though the second contact CT2 appears to be in contact with the drain region DR from an X-Y plane view.

In addition, referring to FIG. 7A, an intermediate insulating layer 142 may be arranged between the word line WL and the drain region DR. In embodiments, the intermediate insulating layer 142 may be formed to a thickness such that the word line WL is not electrically connected to the drain region DR.

A first source region SR1 and a second source region SR2 of the integrated circuit device 100d may have different forms or shapes from each other. In the integrated circuit devices 100, 100a, 100b, and 100c described above, the source regions SR are shown to be mirror-symmetrical to each other with the buried insulating layer 140 therebetween. In the integrated circuit device 100d of FIGS. 7A and 7B, the first and second source regions SR1 and SR2 are not mirror-symmetrical to each other. The lower surface of the first source region SR1 may be spaced apart from the upper surface of the bit line BL by a certain distance. On the other hand, the second source region SR2 may be in contact with the bit line BL. That is, the vertical level of the lower surface of the second source region SR2 may be less or lower than the vertical level of the lower surface of the first source region SR1, e.g., relative to the bit line BL. That is, a bottom surface of the second source region SR2 may be closer to the bit line BL than a bottom surface of the first source region SR1.

In addition, in the integrated circuit device 100d, the ferroelectric layer FL is shown to have an “L” shape rather than a “U” shape in cross-section. That is, the ferroelectric layer FL may extend in the second direction on the first sidewall of the channel layer, and in the first direction on an upper surface of a source region that is between the channel layer and the bit line. However, the ferroelectric layer FL may also have the “U” shape, like the integrated circuit devices 100, 100a, 100b, 100c, 100e, and 100f. That is, the ferroelectric layer FL may extend in the second direction on opposing sidewalls of the word line, and in the first direction on a surface of the word line between the opposing sidewalls. Conversely, while the integrated circuit devices 100, 100a, 100b, 100c, 100e, and 100f described herein are shown to include a “U” shaped ferroelectric layer FL, the ferroelectric layers FL may also be formed in an “L” shape in cross-section.

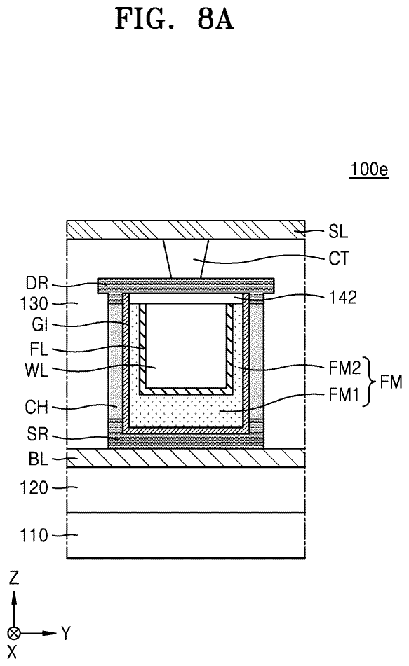

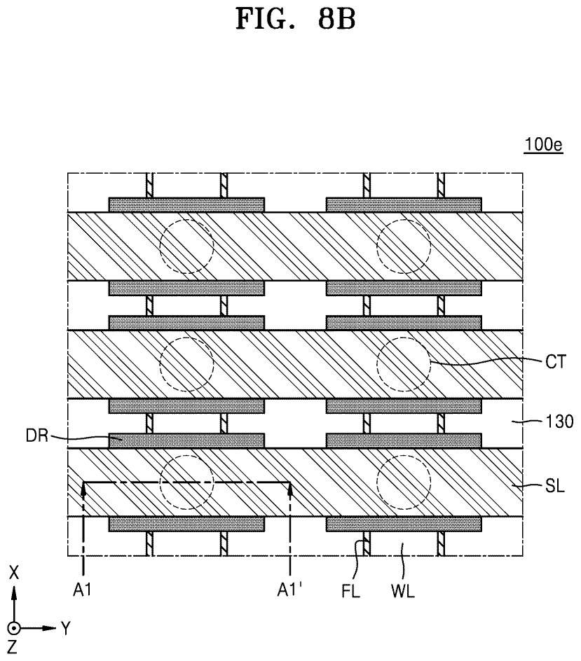

FIG. 8A and FIG. 8B are a cross-sectional view and a top view of a portion of a cell array area in FIG. 2, respectively, according to embodiments. Specifically, FIG. 8A may be a cross-sectional view taken along line A1-A1′ in FIG. 8B.

Referring to FIGS. 8A and 8B, an integrated circuit device 100e may have a merged gate structure. That is, the word lines WL may be merged into one, wherein the floating metal layer FM, the ferroelectric layer FL, the gate insulating layer GI, the source region SR, and the drain region DR may also be merged into one, respectively. That is, the floating metal layer FM, the ferroelectric layer FL, the gate insulating layer GI, the source region SR, and/or the drain region DR may be arranged such that the respective layers are continuous, without the buried insulating layer 140 therebetween.

In addition, referring to FIG. 8A, an intermediate insulating layer 142 may be arranged between the word line WL and the drain region DR. In embodiments, the intermediate insulating layer 142 may be formed to a thickness such that the word line WL is not electrically connected to the drain region DR.

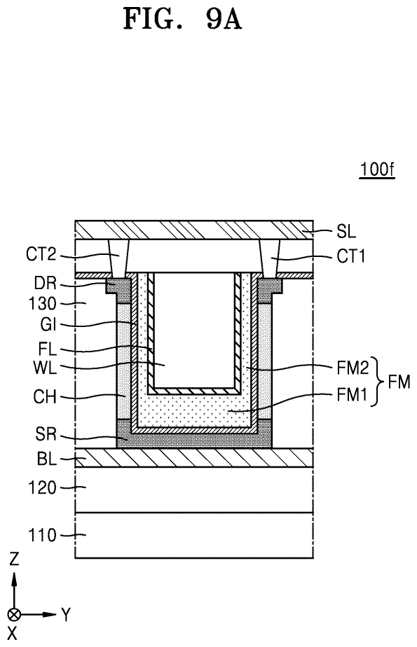

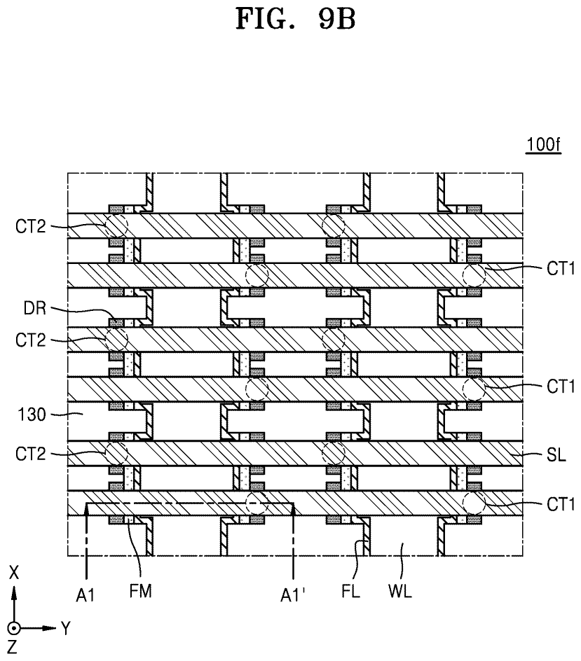

FIG. 9A and FIG. 9B are a cross-sectional view and a top view of a portion of a cell array area in FIG. 2, respectively, according to embodiments. Specifically, FIG. 9A may be a cross-sectional view taken along line A1-A1′ in FIG. 9B.

Referring to FIGS. 9A and 9B, an integrated circuit device 100f may have a merged gate structure. That is, the word lines WL may be merged into one, wherein the floating metal layer FM, the ferroelectric layer FL, and the gate insulating layer GI may also be merged into one. However, unlike the integrated circuit device 100e shown in FIG. 8A and FIG. 8B, the source region SR may be separated from the drain region DR. For example, as shown in FIG. 9A, the drain region DR may not be continuous.

The contacts CT1 and CT2 of the integrated circuit device 100f may be formed in a zigzag form from a plan view. That is, the first contact CT1 and the second contact CT2 may be formed on different source lines SL. Thus, while the first contact CT1 is in direct contact with the drain region DR, the second contact CT2 formed on the other source line SL may be spaced apart from the drain region DR in the cross-section taken along line A1-A1′ even though the second contact CT2 appears to be in contact with the drain region DR from an X-Y plane view.

In addition, referring to FIG. 9A, an intermediate insulating layer (not shown) may be arranged between the word line WL and the drain region DR. In embodiments, the intermediate insulating layer may be formed to a thickness such that the word line WL is not electrically connected to the drain region DR.

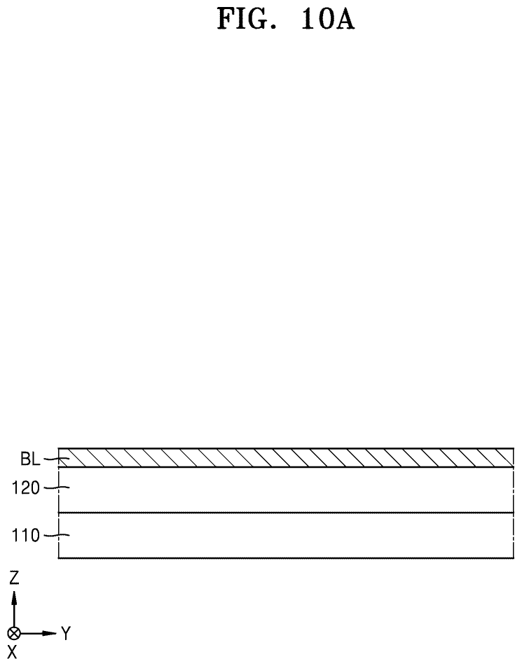

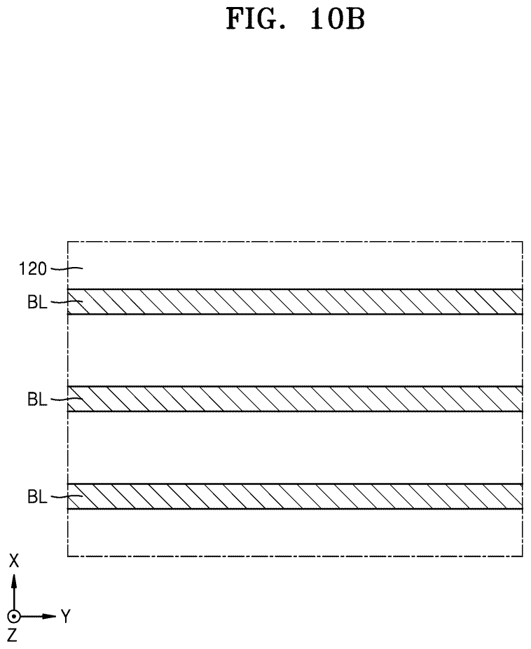

FIGS. 10A, 10B, 11A, 11B, 12A, 12B, 13A, 13B, 14A, 14B, 15, 16A, 16B, 17A, 17B, 18, 19A, 19B, 20A, 20B, 21A, 21B, 22A, 22B, 23A, 23B, 24A, and 24B are schematic diagrams illustrating a method of manufacturing an integrated circuit device, according to embodiments. Specifically, FIGS. 10A, 11A, 12A, 13A, 14A, 16A, 17A, 18, 19A, 20A, 21A, 22A, 23A, and 24A are cross-sectional views of each structure formed during the manufacturing process, and FIGS. 10B, 11B, 12B, 13B, 14B, 15, 16B, 17B, 19B, 20B, 21B, 22B, 23B, and 24B are top views of each structure formed during the manufacturing process.

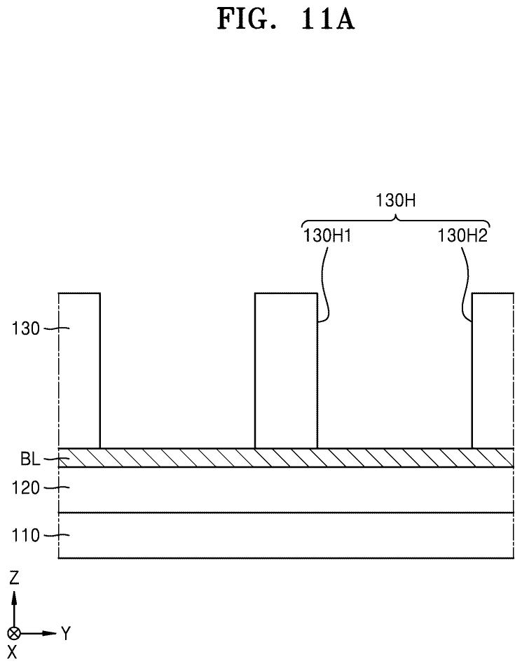

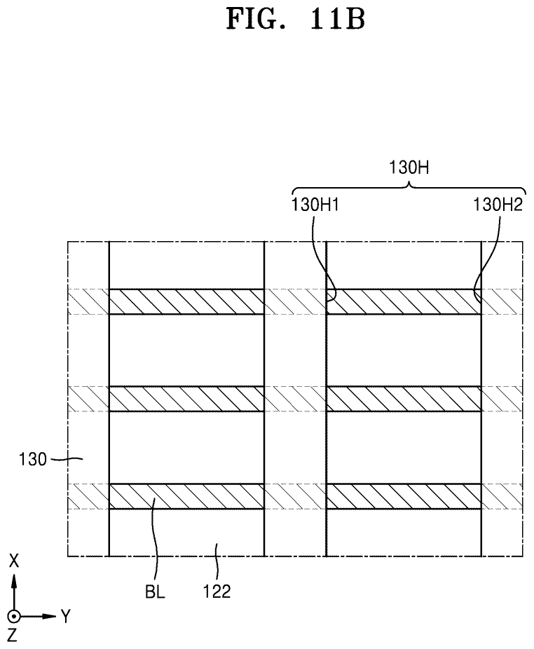

Referring to FIGS. 10A, 10B, 11A, and 11B, a lower insulating layer 120 is formed on a substrate 110. Then, a plurality of bit lines BL extending in the second horizontal direction (Y direction) and a first insulating layer 122 (see FIG. 11B) filling the space between the plurality of bit lines BL may be formed on the lower insulating layer 120.

A mold insulating layer 130 may then be formed on the plurality of bit lines BL and the first insulating layer 122. The mold insulating layer 130 may be formed to have a relatively large height or thickness in the vertical direction (Z direction) using at least one of silicon oxide, silicon nitride, and/or silicon oxynitride.

Next, a mask pattern (not shown) may be formed on the mold insulating layer 130, and a plurality of holes 130H may be formed using the mask pattern as an etch mask (see FIGS. 11A and 11B). The upper surface of the bit line BL may be exposed at the bottom of the plurality of holes 130H. Each of the plurality of holes 130H may extend in the first horizontal direction (X direction) and may include a first sidewall 130H1 and a second sidewall 130H2 opposite to each other.

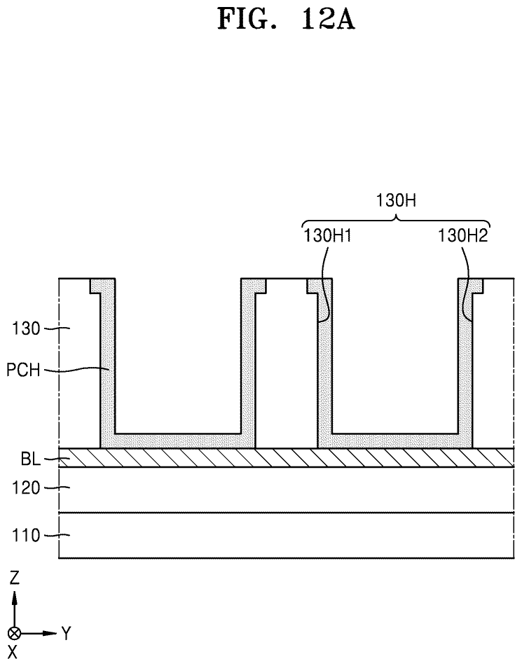

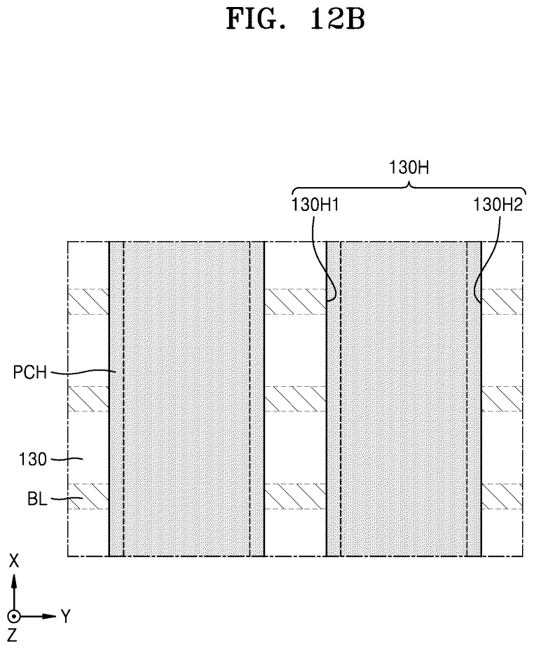

Referring to FIGS. 12A and 12B, a preliminary channel layer PCH may be formed on the inner wall of the hole 130H of the mold insulating layer 130. The preliminary channel layer PCH may be formed on the upper surface of the mold insulating layer 130 and on the inner wall of the hole 130H of the mold insulating layer 130. The preliminary channel layer PCH may be formed to have a U-shaped vertical cross-section. In embodiments, the upper surface of the preliminary channel layer PCH may be arranged on the same plane as the upper surface of the mold insulating layer 130.

In embodiments, the preliminary channel layer PCH may be formed using at least one of polysilicon, SiGe, and/or a two-dimensional material, such as hexagonal boron nitride, transition metal dichalcogenide, or graphene. In embodiments, the preliminary channel layer PCH may be formed by a chemical vapor deposition process or an atomic layer deposition process.

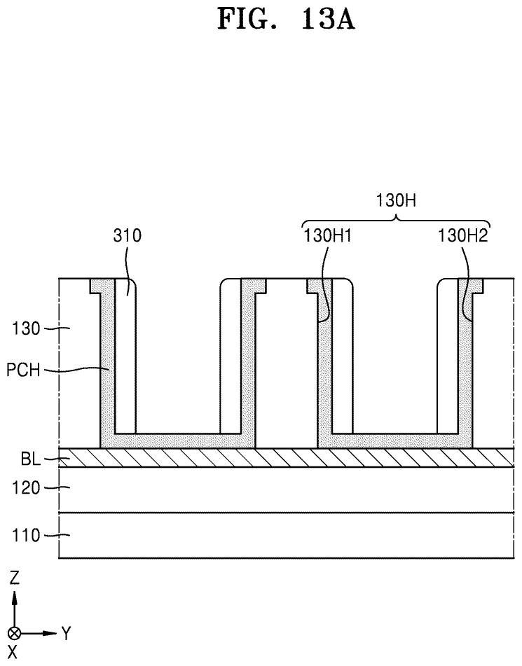

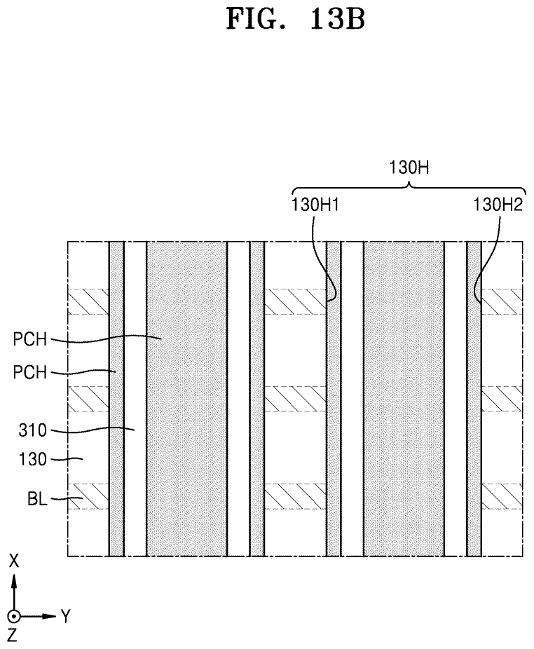

Referring to FIGS. 13A and 13B, an insulating layer (not shown) may be formed on the mold insulating layer 130 and the preliminary channel layer PCH, and an anisotropic etching process may be performed on the insulating layer to form a spacer 310 on the inner wall of the hole 130H of the mold insulating layer 130.

In embodiments, the spacer 310 may not cover but may leave exposed a portion of the upper surface of the preliminary channel layer PCH disposed on the sidewall of the hole 130H and a portion of the upper surface of the preliminary channel layer PCH disposed on the bottom of the hole 130H.

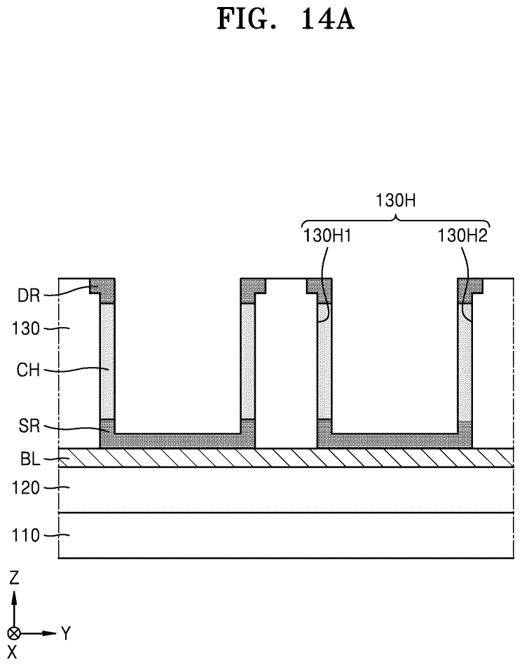

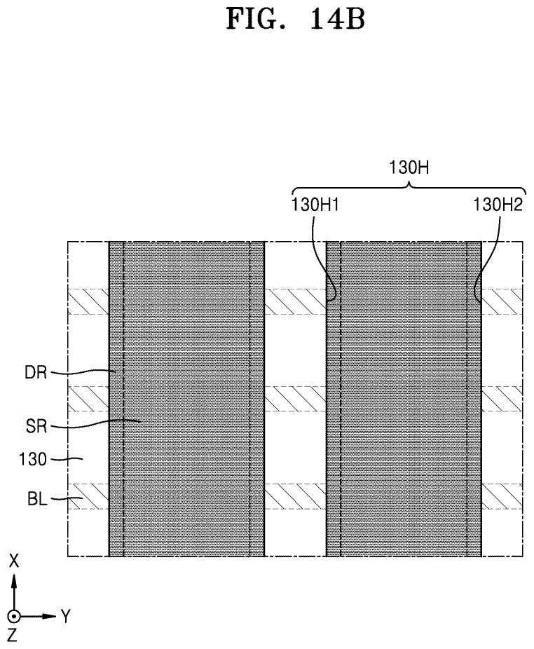

Referring to FIGS. 14A and 14B, the spacer 310 may be removed after forming a source region SR and a drain region DR.

Specifically, an ion implantation process may be performed on the exposed surface of the preliminary channel layer PCH to form the source region SR on a portion of the preliminary channel layer PCH disposed on the bottom of the hole 130H of the mold insulating layer 130 and to form the drain region DR on a portion of the preliminary channel PCH disposed on the sidewall of the hole 130H. In embodiments, the source region SR and the drain region DR may include regions heavily doped with p-type impurities.

The drain region DR may be formed by implanting impurity ions to a certain height or depth from the upper surface of the mold insulating layer 130. The preliminary channel layer PCH disposed below the drain region DR may be covered by the spacer 310 (see FIGS. 13A and 13B) not to implant impurity ions.

Next, the spacer 310 may be removed and the mask pattern (not shown) extending in the second horizontal direction (Y direction) may be formed on the preliminary channel layer PCH. The mask pattern may then be used as an etch mask to remove portions of the preliminary channel layer PCH to form a plurality of channel layers CH.

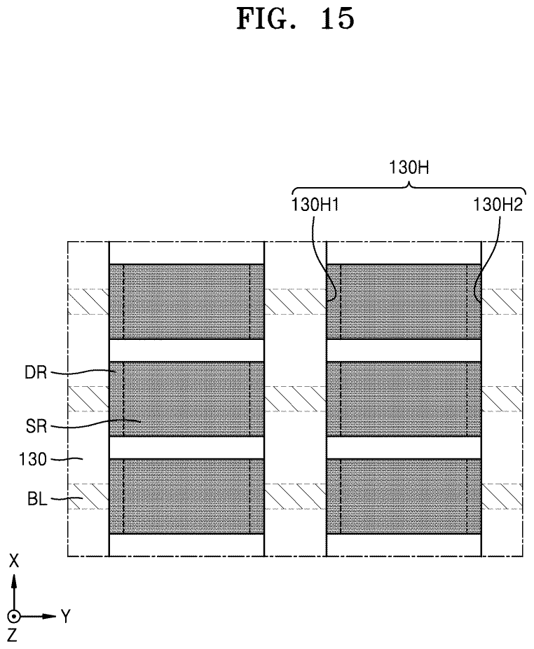

Referring to FIG. 15, a plurality of source regions SR and a plurality of drain regions DR extending in the first horizontal direction (X direction) may be spaced apart from each other by using the mask pattern (not shown) extending in the second horizontal direction (Y direction). In other embodiments, the process may be removed together in the process of removing portions of the preliminary channel layer PCH described with reference to FIGS. 14A and 14B. That is, one source region SR may thus be arranged at a point where one hole 130H and one bit line BL overlap, wherein the channel layer CH and the drain region DR may be arranged on both ends of the source region SR. Components or layers described with reference to “overlap” in a particular direction may be at least partially obstructed by one another when viewed along a line extending in the particular direction or in a plane perpendicular to the particular direction.

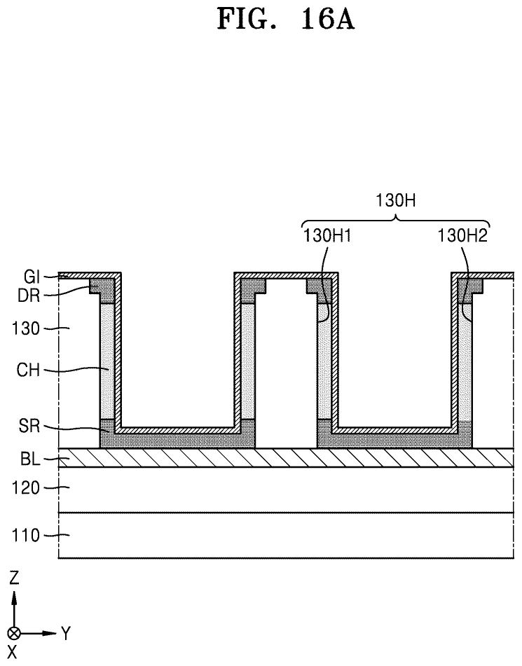

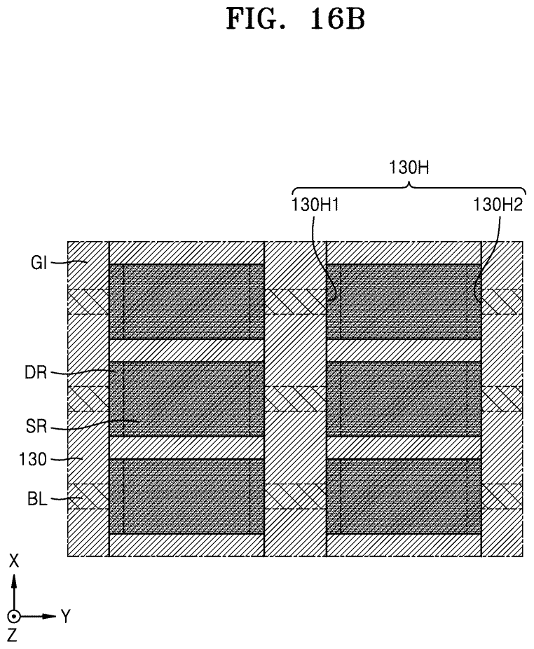

Referring to FIGS. 16A and 16B, a gate insulating layer GI may be formed on the inner wall of the hole 130H. The gate insulating layer GI may be arranged on the upper surface of the mold insulating layer 130, the sidewall of the drain region DR, the sidewall of the channel layer CH, and the upper surface of the source region SR, and may have a U-shaped vertical cross-section.

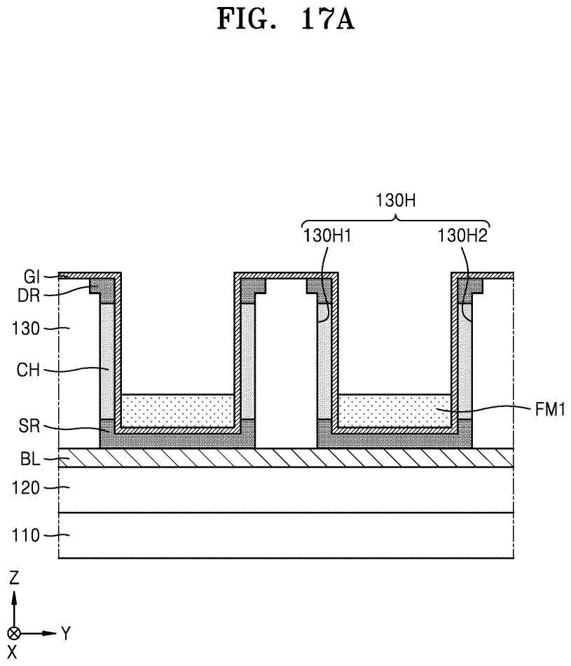

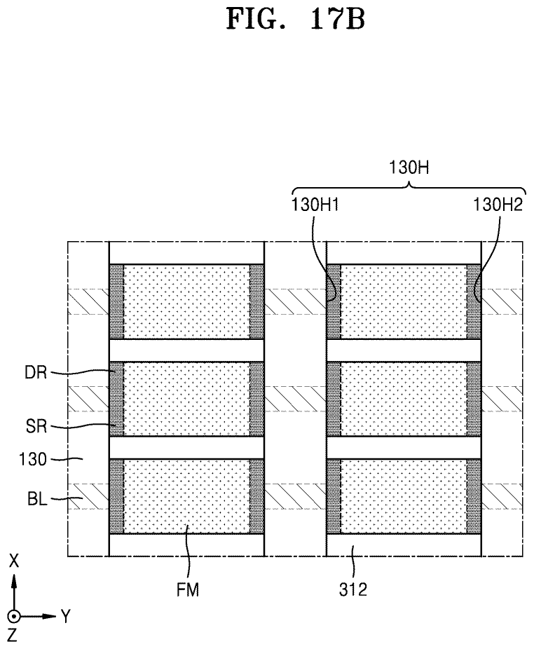

Referring to FIGS. 17A and 17B, a first floating metal layer FM1 having a certain thickness may be formed on the bottom surface of the hole 130H. The first floating metal layer FM1 may have a conformal thickness in the vertical direction (Z direction) and may extend in the second horizontal direction (Y direction).

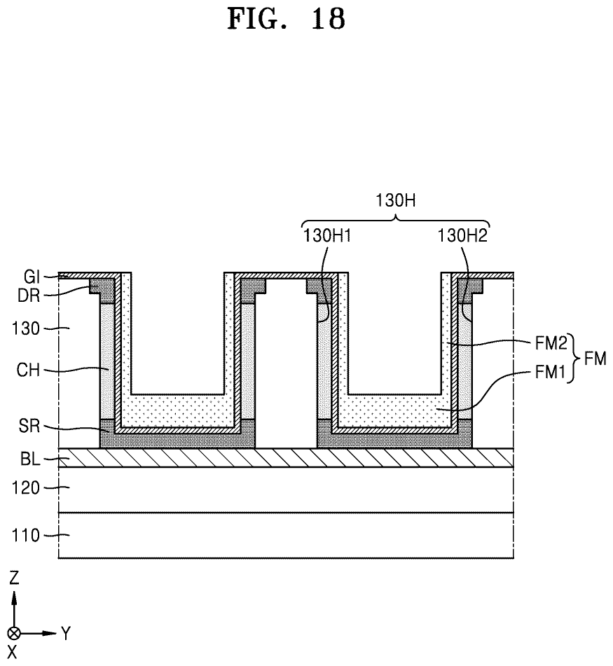

Referring to FIG. 18, a second floating metal layer FM2 having a certain thickness and extending in the vertical direction (Z direction) may be formed on the sidewall of the hole 130H. The gate insulating layer GI disposed on the sidewall and the lower surface of the hole 130H may be covered by the first and second floating metal layers FM1 and FM2. In embodiments, the width of the second floating metal layer FM2 in the second horizontal direction (Y direction) may be less than the thickness of the first floating metal layer FM1 in the vertical direction (Z direction).

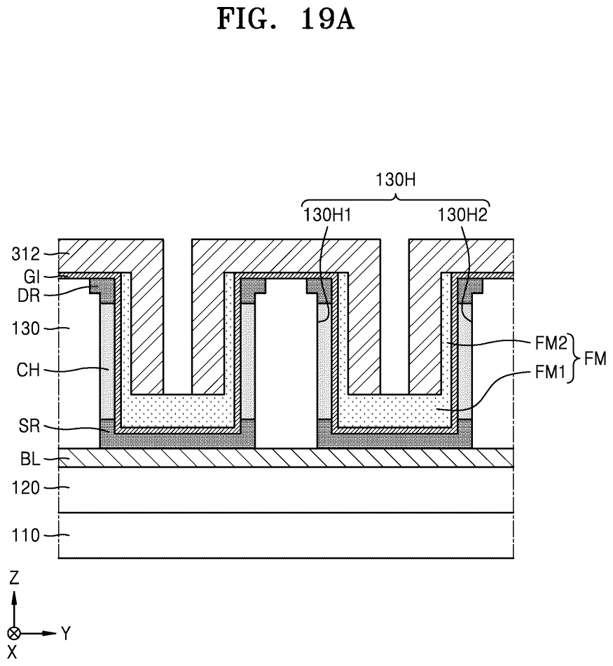

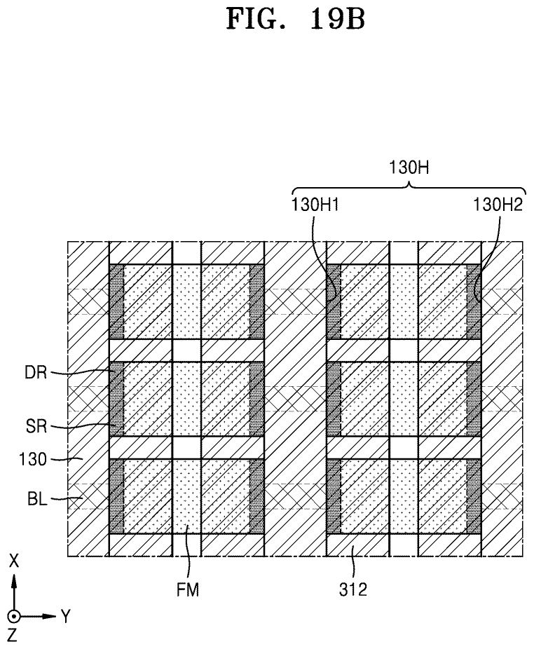

Referring to FIGS. 19A and 19B, a spacer 312 may be formed to cover the exposed gate insulating layer GI, the sidewall of the second floating metal layer FM2, and a portion of both ends of the first floating metal layer FM1. In embodiments, the spacer 312 may include the same material as the spacer 310 (see FIGS. 13A and 13B) but may also include different materials.

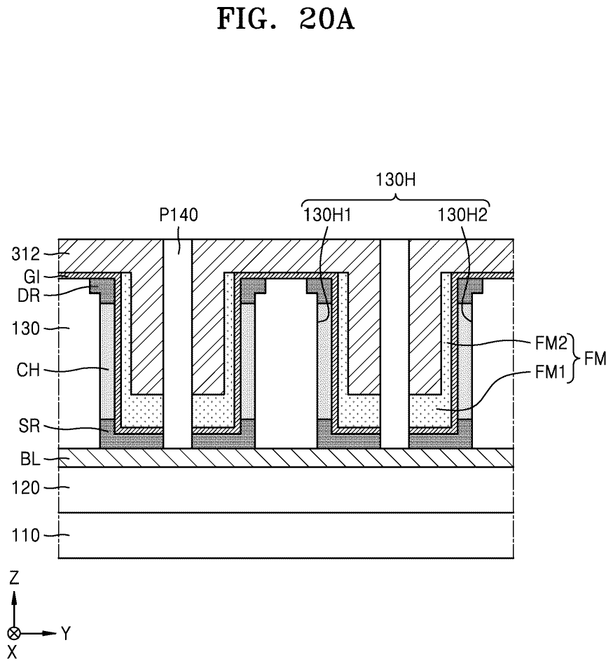

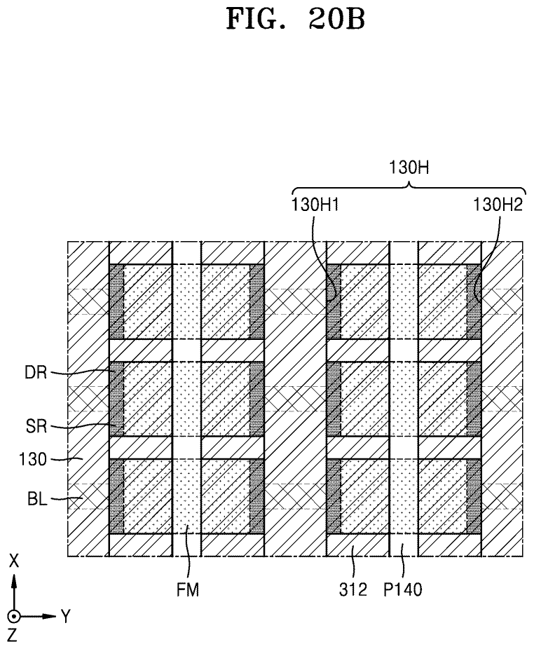

Referring to FIGS. 20A and 20B, the spacer 312 may be utilized as an etch mask to remove the exposed area of the first floating metal layer FM1. In a process in which a part of the first floating metal layer FM1 is removed, the gate insulating layer GI and the source region SR disposed on the lower surface of the exposed first floating metal layer FM1, may be removed together. That is, the etching process using the spacer 312 as a mask may be performed until the upper surface of the bit line BL is exposed.

After the etching process is completed, a preliminary buried insulating layer P140 may be formed to fill the removed area. The preliminary buried insulating layer P140 may be formed to fill the spaces between the source region SR, the gate insulating layer GI, and the first floating metal layer FM1 which are partially separated by the etching process and to cover up to the same vertical level as the upper surface of the spacer 312.

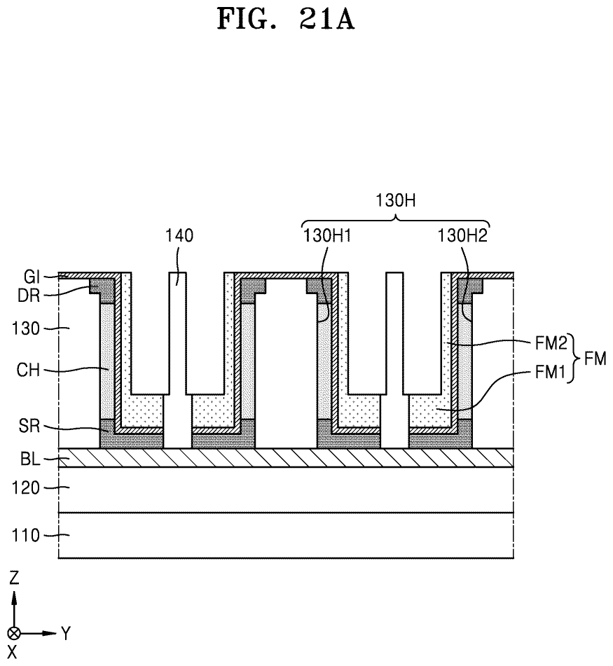

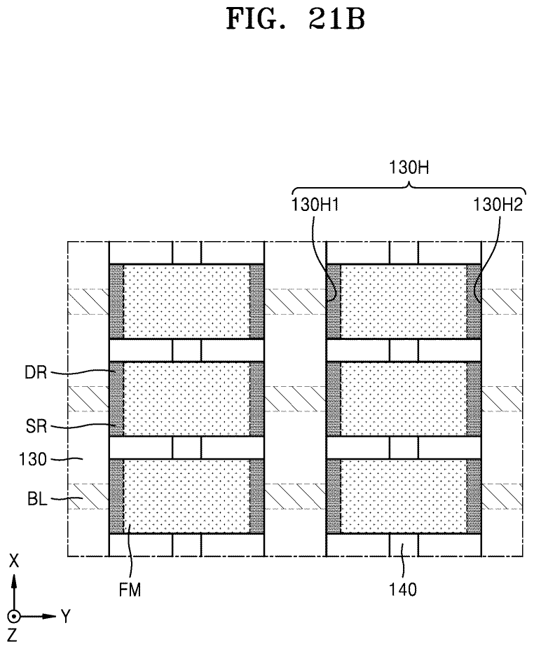

Referring to FIGS. 21A and 21B, the spacer 312 may be removed. In a process of removing the spacer 312, a portion of the wall surface of the preliminary buried insulating layer P140 may be etched together. Thus, the width of the upper end of the buried insulating layer 140 may be less than the width of the lower end thereof in the second horizontal direction (Y direction). However, this is merely an example. The width of the buried insulating layer 140 may be the same as that of the preliminary buried insulating layer 140P (see FIGS. 20A and 20B) in the horizontal direction (Y direction) at all vertical levels.

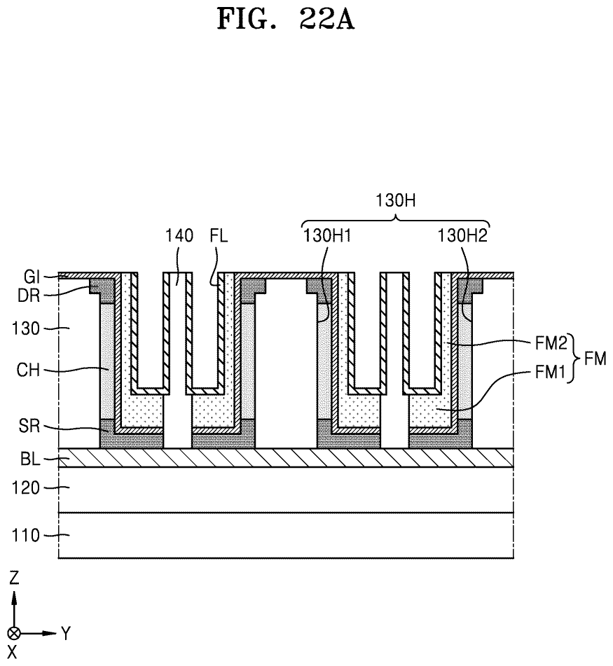

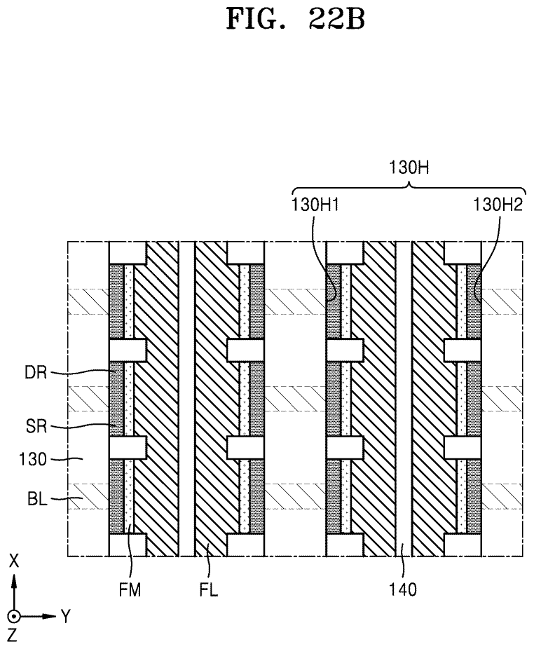

Referring to FIGS. 22A and 22B, a ferroelectric layer FL may be formed. The ferroelectric layer FL may be formed in the “U” shape with a conformal thickness surrounding the sidewall of the buried insulating layer 140 and the sidewall and the lower surface of the floating metal layer FM. The ferroelectric layer FL is illustrated as being a single layer for convenience of illustration. However, the ferroelectric layer FL may be formed with a laminate structure of different ferroelectric layers, ferroelectric and dielectric layers, ferromagnetic and antiferroelectric layers, or antiferromagnetic and dielectric layers as described above. In embodiments, the thickness of the ferroelectric layer FL may not be greater than 20 nm. In addition, in other embodiments, the ferroelectric layer FL may surround the sidewall and the lower surface of the floating metal layer FM but may not be formed on the sidewall of the buried insulating layer 140. That is, the ferroelectric layer FL may be formed in the “L” shape rather than the “U” shape.

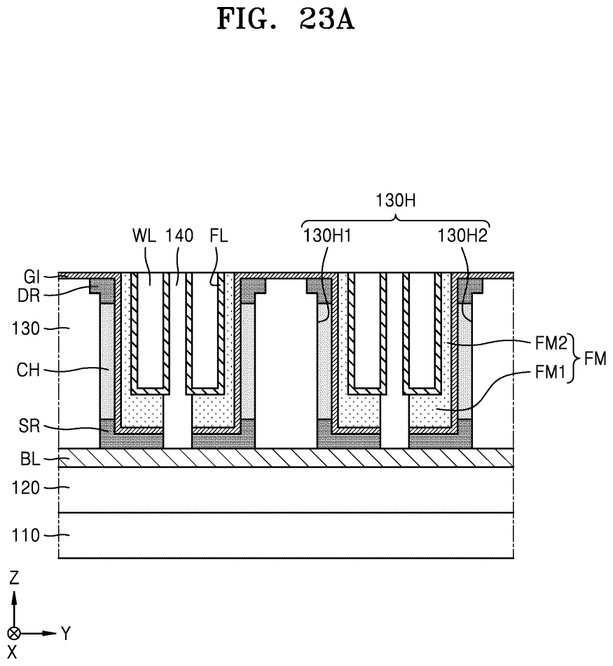

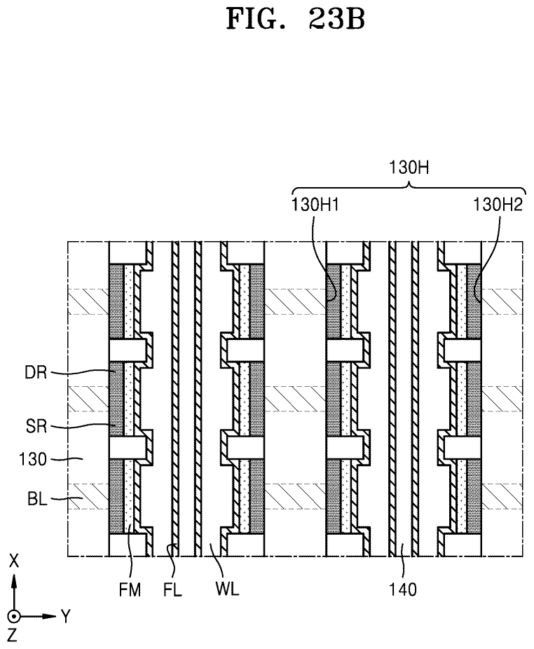

Referring to FIGS. 23A and 23B, a word line WL may be formed on the ferroelectric layer FL. The word line WL may be formed to fill the space surrounded by the ferroelectric layer FL.

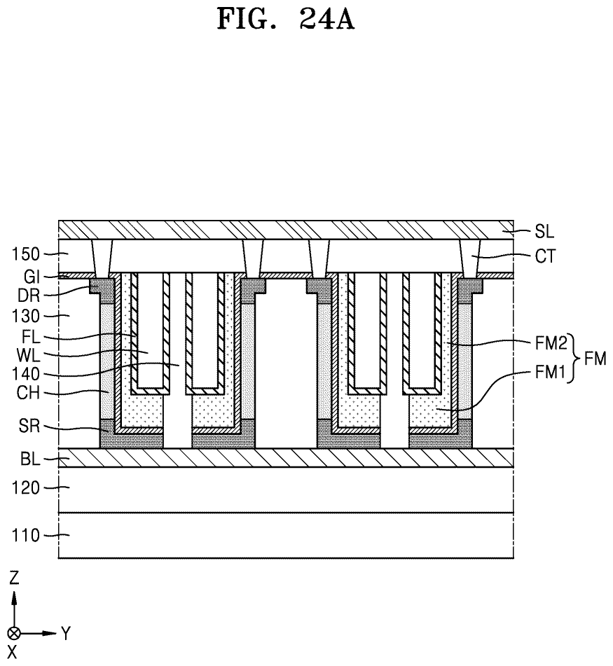

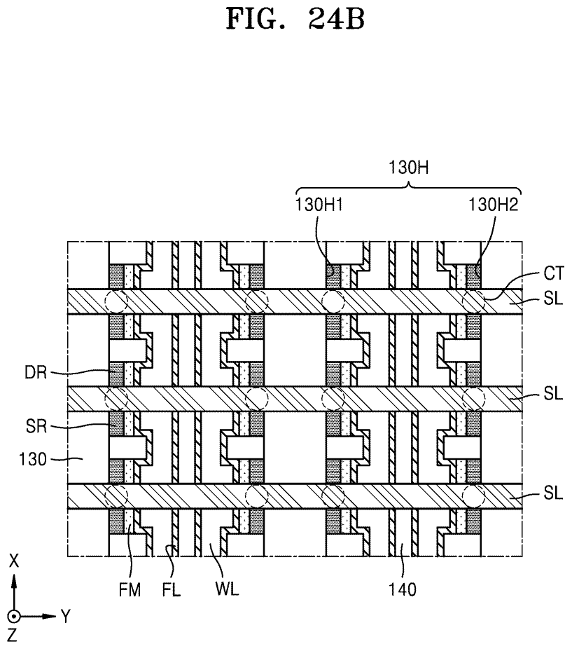

Referring to FIGS. 24A and 24B, an upper insulating layer 150 may be formed on the mold insulating layer 130 and the buried insulating layer 140. A portion of the upper insulating layer 150 may be removed to form a contact hole (not shown) that exposes the upper surface of the drain region DR.

A contact CT may then be formed inside the contact hole and a source line SL electrically connected with the contact CT may be formed on the upper insulating layer 150.

The above-described process may be performed to complete the integrated circuit device 100 shown in FIG. 3A and FIG. 3B.

While the inventive concept has been particularly shown and described with reference to embodiments thereof, it will be understood that various changes in form and details may be made therein without departing from the scope of the following claims.

What is claimed is:

1. An integrated circuit device, comprising:
a substrate;
a bit line extending on the substrate in a first direction parallel to an upper surface of the substrate;
a channel layer extending on the bit line in a second direction perpendicular to the upper surface of the substrate and comprising a first sidewall;
a floating metal layer spaced apart from the channel layer in the first direction;
a gate insulating layer between the floating metal layer and the channel layer, wherein the gate insulating layer is on the first sidewall of the channel layer;
a word line on at least one sidewall of the floating metal layer and extending in a third direction parallel to the upper surface of the substrate and crossing the first direction;
a ferroelectric layer between the word line and the at least one sidewall of the floating metal layer; and
a source line electrically connected to the channel layer and extending in the first direction,
wherein the floating metal layer comprises a horizontal extension portion extending in the first direction and a vertical extension portion extending in the second direction, and
wherein an area of contact between the channel layer and the gate insulating layer is greater than an area of contact between the ferroelectric layer and the floating metal layer.

2. The integrated circuit device of claim 1, wherein a thickness of the horizontal extension portion of the floating metal layer in the second direction is greater than a thickness of the vertical extension portion of the floating metal layer in the first direction.

3. The integrated circuit device of claim 1, wherein the channel layer comprises polysilicon, silicon germanium, an oxide semiconductor material, or a two-dimensional material.

4. The integrated circuit device of claim 1, wherein a thickness of the ferroelectric layer is not greater than 20 mm.

5. The integrated circuit device of claim 1, wherein the floating metal layer comprises a hafnium (Hf)-based oxide film, and
wherein the floating metal layer comprises a dopant of zirconium (Zr), silicon (Si), aluminum (Al), yttrium (Y), gadolinium (Gd), lanthanum (La), scandium (Sc), strontium (Sr), and/or combinations thereof.

6. The integrated circuit device of claim 1, wherein the ferroelectric layer comprises two material layers selected from a ferroelectric material layer, an antiferroelectric material layer, and a dielectric material layer, wherein the two material layers are alternately stacked one or more times.

7. The integrated circuit device of claim 1, wherein the ferroelectric layer comprises first and second ferroelectric material layers comprising different ferroelectric materials, wherein the first and second ferroelectric material layers are alternately stacked one or more times.

8. The integrated circuit device of claim 1, wherein the ferroelectric layer comprises a first material having a different work function from a second material in the floating metal layer and the word line.

9. The integrated circuit device of claim 1, further comprising:
a source region between the channel layer and the bit line; and
a drain region between the channel layer and the source line.

10. The integrated circuit device of claim 1, wherein the ferroelectric layer extends in the second direction on opposing sidewalls of the word line, and in the first direction on a surface of the word line between the opposing sidewalls.

11. The integrated circuit device of claim 1, wherein the ferroelectric layer extends in the second direction on the first sidewall of the channel layer, and in the first direction on an upper surface of a source region that is between the channel layer and the bit line.

12. The integrated circuit device of claim 1, wherein the integrated circuit device comprises a capacitor-less dynamic random-access memory (DRAM) device.

13. An integrated circuit device, comprising:
a substrate;
a bit line extending on the substrate in a first direction parallel to an upper surface of the substrate;
a source region on the bit line and comprising p-type impurities;
a channel layer on the source region, extending in a second direction perpendicular to the upper surface of the substrate, and comprising a first sidewall;
a gate insulating layer on the first sidewall of the channel layer and on an upper surface of the source region;
a floating metal layer comprising a first floating metal layer and a second floating metal layer, wherein the first floating metal layer is on the upper surface of the source region, and the second floating metal layer is on the first sidewall of the channel layer, wherein the gate insulating layer is between the channel layer and the floating metal layer and between the source region and the floating metal layer;
a word line on an upper surface of the first floating metal layer;
a ferroelectric layer between the first floating metal layer and the word line and between the second floating metal layer and the word line;
a drain region on an upper surface of the channel layer and comprising p-type impurities; and
a source line electrically connected to the drain region and extending in the first direction,
wherein a thickness of the first floating metal layer in the second direction is greater than a thickness of the second floating metal layer in the first direction, and
wherein an area of contact between the channel layer and the gate insulating layer is greater than an area of contact between the ferroelectric layer and the floating metal layer.

14. The integrated circuit device of claim 13, wherein the channel layer comprises polysilicon, silicon germanium, an oxide semiconductor material, or a two-dimensional material.

15. The integrated circuit device of claim 13, wherein a thickness of the ferroelectric layer is not greater than 20 nm.

16. The integrated circuit device of claim 13, wherein the ferroelectric layer comprises:
two material layers selected from a ferroelectric material layer, an antiferroelectric material layer, and a dielectric material layer, wherein the two material layers are alternately stacked one or more times; or
first and second ferroelectric material layers that are alternately stacked one or more times, wherein the first and second ferroelectric material layers comprise different ferroelectric materials.

17. The integrated circuit device of claim 13, wherein the floating metal layer comprises a hafnium-based oxide film, and
wherein the floating metal layer comprises a dopant of zirconium (Zr), silicon (Si), aluminum (Al), yttrium (Y), gadolinium (Gd), lanthanum (La), scandium (Sc), strontium (Sr), and/or combinations thereof.

18. The integrated circuit device of claim 13, wherein the ferroelectric layer comprises a first material having a different work function from a second material in the floating metal layer and the word line.

19. An integrated circuit device, comprising:
a substrate;
a bit line extending on the substrate in a first direction parallel to an upper surface of the substrate;
a mold insulating layer on the substrate and on the bit line and comprising a hole therein;
a source region in the hole of the mold insulating layer, on an upper surface of the bit line, and comprising p-type impurities;
a channel layer in the hole of the mold insulating layer and extending on the source region in a second direction perpendicular to the upper surface of the substrate, the channel layer comprising polysilicon, silicon germanium, an oxide semiconductor material, or a two-dimensional material, and having a first sidewall and a second sidewall opposite each other, wherein the second sidewall is in contact with the mold insulating layer;
a gate insulating layer and a floating metal layer in the hole of the mold insulating layer, the gate insulating layer extending in the second direction on the first sidewall of the channel layer and in the first direction on an upper surface of the source region;
a ferroelectric layer in the hole of the mold insulating layer and conformally extending on a sidewall of a vertical extension portion of the floating metal layer and an upper surface of a horizontal extension portion of the floating metal layer;
a word line in the hole of the mold insulating layer and on the ferroelectric layer;
a drain region in the hole of the mold insulating layer, on an upper surface of the channel layer, and comprising p-type impurities; and
a source line electrically connected to the drain region and extending in the first direction,
wherein a thickness of the horizontal extension portion of the floating metal layer in the second direction is greater than a thickness of the vertical extension portion of the floating metal layer in the first direction,
wherein an area of contact between the channel layer and the gate insulating layer is greater than an area of contact between the ferroelectric layer and the floating metal layer, and
wherein a thickness of the ferroelectric layer is not greater than 20 nm.

20. The integrated circuit device of claim 19, wherein the ferroelectric layer comprises:
two material layers selected from a ferroelectric material layer, an antiferroelectric material layer, and a dielectric material layer, wherein the two material layers are alternately stacked one or more times; or
first and second ferroelectric material layers that are alternately stacked one or more times, wherein the first and second ferroelectric material layers comprise different ferroelectric materials,
wherein the floating metal layer comprises a hafnium-based oxide layer comprising a dopant of zirconium (Zr), silicon (Si), aluminum (Al), yttrium (Y), gadolinium (Gd), lanthanum (La), scandium (Sc), strontium (Sr), and/or combinations thereof.
